(19) United States
(12) Patent Application Publication
(10) Pub. No.: US 2006/0062053 A1
(43) Pub. Date: Mar. 23, 2006

(54) Authentication output system, network device, device utilizing apparatus, output control program, output request program, and authentication output method

(76) Inventors: Shinya Taniguchi, Suwa-shi (JP); Naruhide Kitada, Nagano-ken (JP)

Correspondence Address: HARNESS, DICKEY & PIERCE, P.L.C., P.O. BOX 828, BLOOMFIELD HILLS, MI, 48303, US

(21) Appl. No.: 11/211,171

(22) Filed: Aug. 24, 2005

(30) Foreign Application Priority Data
Aug. 25, 2004 (JP) 2004-244838
Jun. 23, 2005 (JP) 2005-183300

(51) Int. Cl. G11C 7/10

(52) U.S. Cl. 365/189.05

(57) ABSTRACT

An authentication output system including a network device for performing an output operation based on output data and an output data storing device for storing the output data, wherein the network device and the output data storing device are communicably connected, and the network device performs the output operation via authentication.

### BACKGROUND OF THE INVENTION

1. Technical Field

The present invention relates to a system, a device, an apparatus, a program and a method for performing an output operation such as printing, or the like on the basis of output data, and particularly relates to an authentication output system, a network device, a device utilizing apparatus, an output control program, an output request program and an authentication output method able to reliably perform the output operation without adding any special program to a host terminal even when many output requests are simultaneously generated.

2. Related Art

When printing is performed by a network printer and a host terminal of a user exists in a place separated from the network printer, an output state of printed matters is attained until the user goes to the place of the network printer. Therefore, there is a possibility that the contents of the printed matters are seen by others. Therefore, it is desirably required to arrange a security function in the network printer.

For example, there is conventionally a printing system disclosed in JP-A-11-353137 as a technique for improving the security of the network-printer.

In the invention described in JP-A-11-353137, when a document is first printed from the host terminal, a print command (data for describing commands for processing the printing to the printer) with a password number is transmitted to the network printer. In the network printer, print data are generated on a frame memory on the basis of the received print command, and are then compressed and accumulated. The user then actually comes to the arranging place of the network printer, and inputs the password number to the network printer, and starts printing processing by using the accumulated compression data for the first time at that time. Further, when the total amount of the compression data exceeds the capacity of the accumulation in the network printer, the compression data of a job are deleted in a FIFO (First In First Out) format.

However, the host terminal generates the password number in the invention described in JP-A-11-353137. Therefore, a problem exists in that a program other than a program of a printer driver, or the like, i.e., a special program for generating the password number must be added. The addition of the program is a burden on the user.

Further, when the total amount of the compression data exceeds the capacity of the accumulation, the compression data are deleted from the compression data of a job previously accumulated. Therefore, when many print requests are simultaneously generated, there is a possibility that the compression data of uncompleted printing jobs are deleted, and a problem exists in that no printing is reliably performed. With respect to this problem, a construction for accumulating the print data in the host terminal and acquiring the print data from the host terminal by the network printer after authentication is considered.

However, in this construction, the network printer cannot be necessarily connected to all the host terminals. Therefore, when no print data can be acquired, no printing can be performed. For example, when the host terminal is located inside a fire wall and the network printer is located outside the fire wall, no network printer can directly get access to the host terminal within the fire wall. Therefore, no network printer can acquire the print data.

Such a problem is similarly encountered in a case in which a display device such as a projector, an LCD (Liquid Crystal Display) device, or the like is connected to the network and display is performed by the display device, or the like as well as the printing case using the network printer.

### SUMMARY

Therefore, an advantage of the invention is to provide an authentication output system, a network device, a device utilizing apparatus, an output control program, an output request program and an authentication output method able to reliably perform an output operation without adding any special program to the host terminal even when many output requests are simultaneously generated.

To achieve the above advantage, the authentication output system of mode 1 is an authentication output system including a network device for performing an output operation on the basis of output data and an output data storing device for storing the output data, wherein the network device and the output data storing device are communicably connected, and the network device performs the output operation via authentication,

the network device has an output data receiving unit for receiving the output data, an output data transfer unit for transferring the output data received in the output data receiving unit to the output data storing device, a certification information generating unit for generating certification information used to certify a utilization competency of the output data, a certification information transmitting unit for transmitting the certification information generated in the certification information generating unit to a predetermined output destination, a certification information acquiring unit for acquiring the certification information, a utilization competency judging unit for judging whether there is the utilization competency of the output data on the basis of the certification information acquired in the certification information acquiring unit, an output data acquiring unit for acquiring the output data from the output data storing device, and an output unit for performing the output operation on the basis of the output data acquired in the output data acquiring unit;

the output data acquiring unit acquires the output data from the output data storing device when the utilization competency judging unit judges that there is utilization competency of the output data; and

the output data storing device has an output data memory unit, an output data storing unit for storing the output data transferred from the network device to the output data memory unit, and an output data transmitting unit for transmitting the output data of the output data memory unit to the network device in accordance with an acquiring request from the network device.

In accordance with such a construction, when the output data are received by the output data receiving unit in the network device, the received output data are transferred to the output data storing device by the output data transfer unit. Further, the certification information is generated by the certification information generating unit, and the generated certification information is transmitted to the predetermined output destination by the certification information transmitting unit.

In the output data storing device, the output data transferred from the network device are stored to the output data memory unit by the output data storing unit.

In the network device, the certification information given from a user is acquired by the certification information acquiring unit. When it is judged by the utilization competency judging unit that there is a utilization competency of the output data on the basis of the acquired certification information, the output data are acquired from the output data storing device by the output data acquiring unit.

In the output data storing device, the output data of the output data memory unit are transmitted to the network device by the output data transmitting unit in accordance with an acquiring request from the network device.

In the network device, when the output data are acquired, the output operation is performed by the output unit on the basis of the acquired output data.

Thus, since the certification information is generated in the network device, it is not necessary to add a special program to the host terminal so that a burden on the user is reduced. Further, the output data are stored to an external output data storing device instead of the network device. Accordingly, a large amount of print data can be delayed (an opportunity for making preparations and outputting the print data can be provided) in comparison with the conventional case. When many output requests are simultaneously generated, the likelihood of a no output operation in comparison with the conventional case is reduced. Further, the output data are acquired from the output data storing device having a transfer case of the output data. Accordingly, the connection is reliable and the output data can be comparatively reliably acquired. The occurrence of no output operations is further reduced. Further, since the user can obtain the certification information at the predetermined output destination of the host terminal, or the like, the certification information may be easily obtained.

Here, the certification information acquiring unit may have any construction if this construction is set so as to acquire the certification information. For example, the certification information acquiring unit may be constructed so as to input the certification information from an input device or the like and may also be constructed so as to gain or receive the certification information from an external terminal or the like. Further, the certification information acquiring unit may also be constructed so as to read the certification information from a memory device, a memory medium, or the like. Accordingly, the acquisition includes at least input, gaining, reception and reading-out. Hereinafter, the same contents are set in the network device of mode 6.

Further, the output unit may have any construction if the output unit is constructed so as to perform the output operation on the basis of the output data. For example, the output unit includes a print unit for performing a printing operation on the basis of print data, a display unit for performing a display operation on the basis of display data, or a sound output unit for outputting a voice on the basis of voice data. For example, there are a projector and an LCD device as the network device having the display unit. Hereinafter, the same contents are set in the network device of mode 6.

The certification information is information for certifying the utilization competency of the output data. The certification information may be information able to independently certify the utilization competency of the output data. The certification information may also be information in which it is judged that there is a utilization competency of the output data when predetermined authentication processing is performed on the basis of the certification information and authentication information corresponding to this certification information. As the predetermined authentication processing, for example, there is processing for judging whether the certification information and the authentication information satisfy a predetermined relation, and also judging that there is a utilization competency of the output data when it is judged that the predetermined relation is satisfied. Here, as the satisfaction of the predetermined relation, for example, there is conformity of the certification information and the authentication information, conformity of the authentication information and a result obtained by performing an arithmetic operation by a predetermined arithmetic formula using the certification information, or conformity of a result obtained by performing an arithmetic operation by a predetermined arithmetic formula using the certification information and a result obtained by performing an arithmetic operation by a predetermined arithmetic formula using the authentication information. Hereinafter, the same contents are set in the network device of mode 6, the output control program of mode 13 and the authentication output method of mode 20.

The certification information is information utilized to acquire the output data from the output data storing device. The certification information is conceptually information for knowing that the output data personally made by a user are certainly personally made by the user. Hereinafter, the same contents are set in the network device of mode 6, the output control program of mode 13, and the authentication output method of mode 20.

Further, as the predetermined output destination, for example, there are a device utilizing apparatus for utilizing the network device, a server and other terminals, or a recorder (e.g., a card writer, a memory writer and a CD-ROM writer) or a display device (e.g., a projector and an LCD device) communicably connected to the network device, a data reader-writer connected to a network, and a portable terminal (e.g., a portable telephone, PDA (Personal Digital Assistant)) communicable in the network. Hereinafter, the same contents are set in the network device of mode 6, the output control program of mode 13, and the authentication output method of mode 20.

The output data managing device can be constructed as a device utilizing apparatus for utilizing the network device, a server and other terminals. Therefore, the output data memory unit of comparatively large memory capacity can be utilized, and the memory capacity of the output data memory unit can be easily enlarged. Accordingly, when many output requests are simultaneously generated, it is possible to reduce a possibility that unprocessed output data are deleted. Accordingly, the occurrence of no output operations is reduced. Hereinafter, the same contents are set in the network device of mode 6, the output control program of mode 13 and the authentication output method of mode 20.

For example, the output based on the output data is to perform the output operation in accordance with a procedure and information defined within the output data. Further, when the output data are voice data, the output is to output a sound. When the output data are video data, the output is to generate a video image. When the output data are print data, the output is to perform printing. For example, there are intermediate data of PDL or the like, image data of a bit map or the like, in the print data. If the print data are classified for every data assortment, the print data are converted into a mode understandable by a printer and are printed when the print data are intermediate data. When the print data are image data, the print data are outputted as they are. Hereinafter, the same contents are set in the network device of mode 6, the output control program of mode 13, and the authentication output method of mode 20.

Further, the storage of the output data is to possess the output data, and is not limited to a possessing unit, method and period. For example, the storage of the output data includes accumulation of the output data. Hereinafter, the same contents are set in the network device of mode 6, the output control program of mode 13, and the authentication output method of mode 20.

In the authentication output system of mode 1, the authentication output system of mode 2 is characterized in that the output data transfer unit transfers the output data received by the output data receiving unit and device identification information for discriminating the network device to the output data storing device;

the output data storing unit correspondingly sets and stores the output data transferred from the network device and the device identification information to the output data memory unit;

the output data acquiring unit transmits the acquiring request of the output data including the device identification information to the output data storing device; and

the output data transmitting unit reads the output data corresponding to the device identification information included in the acquiring request from the output data memory unit, and transmits the read output data to the network device specified by this device identification information.

In accordance with such a construction, the received output data and device identification information are transferred to the output data storing device by the output data transfer unit in the network device.

In the output data storing device, the output data and the device identification information transferred from the network device are correspondingly set and are stored to the output data memory unit by the output data storing unit.

In the network device, the acquiring request of the output data including the device identification information is transmitted to the output data storing device by the output data acquiring unit.

In the output data storing device, the output data corresponding to the device identification information included in the acquiring request are read from the output data memory unit by the output data transmitting unit. The read output data are transmitted to the network device specified by this device identification information.

Thus, in the output data storing device, the output data transferred from the network device are comparatively reliably provided to this network device. Accordingly, the likelihood of the output data being used in another network device that is unintended by a user is reduced.

Here, when the output data transfer unit and the output data receiving unit are constructed by hardware, the output data transfer unit and the output data receiving unit may be integrally constructed, and may also be separately constructed. Hereinafter, the same contents are set in the network device of mode 7.

In the authentication output system of mode 1 or 2, the authentication output system of mode 3 is characterized in that the network device further has output data dividing unit for dividing the output data received in the output data receiving unit,

the output data transfer unit transfers the divisional output data divided in the output data dividing unit to the plural output data storing devices, and

the output data acquiring unit acquires the divisional output data from the plural output data storing devices, and constructs the output data on the basis of the acquired plural divisional output data.

In accordance with such a construction, the received output data are divided by the output data dividing unit in the network device. The divided divisional output data are transferred to the plural output data storing devices by the output data transfer unit. Further, the divisional output data are acquired from the plural output data storing devices by the output data acquiring unit, and the output data are constructed on the basis of these acquired divisional output data.

Thus, since the output data are divided and stored to the plural output data storing devices, the likelihood that the output data are concentrated onto one output data storing device and its memory capacity is suppressed is reduced.

Here, for example, as a dividing method of the output data, there are a method for equally dividing the output data by the number of output data storing devices (the output data are divided into two portions if there are two output data storing devices), and a method for distributing the output data in accordance with the remaining capacity of the output data storing device (if the remaining capacities of the two output data storing devices are 100 MB and 10 MB, the output data are divided in a ratio of 10 to 1). Hereinafter, the same contents are set in the network device of mode 8, the output control program of mode 15, and the authentication output method of mode 22.

With respect to transmission of the divisional data, it is desirable to transmit at least two divisional data to different output data storing devices from a view point for preventing the output data from being concentrated onto one output data storing device. For example, the divisional data are transmitted to each output data storing device one by one. Hereinafter, the same contents are set in the network device of mode 8, the output control program of mode 15, and the authentication output method of mode 22.

In the authentication output system of mode 1 or 2, the authentication output system of mode 4 is characterized in that the output data transfer unit transfers the output data received in the output data receiving unit to each of the plural output data storing devices, and

the output data acquiring unit acquires the output data from one of the plural output data storing devices.

In accordance with such a construction, the received output data are respectively transferred to the plural output data storing devices by the output data transfer unit in the network device. Further, the output data are acquired from one of the plural output data storing devices by the output data acquiring unit. Thus, even when the operation of one of the output data storing devices storing the output data is disabled before the output operation is performed in the network device, the output data can be acquired from another output data storing device. Accordingly, the occurrence of no output operations is further reduced.

In the authentication output system of one of modes 1 to 4, the authentication output system of mode 5 is characterized in that the network device further has an output data storing device selecting unit for selecting an output data storing device from the plural output data storing devices on the basis of status information showing ability or a resource state of the output data storing device, and

the output data transfer unit transfers the output data to the output data storing device selected by the output data storing device selecting unit.

In accordance with such a construction, one output data storing device is selected from the plural output data storing devices on the basis of the status information by the output data storing device selecting unit in the network device. The output data are transferred to the selected output data storing device by the output data transfer unit.

Thus, the output data storing device is selected in consideration of the ability and the resource state of the output data storing device. Accordingly, the output data may be efficiently transferred, stored and acquired.

Here, for example, information showing the remaining memory capacity of the output data storing device, a communication speed, a data writing-in speed and a data reading speed is included as the status information. Hereinafter, the same contents are set in the network device of mode 10, the output control program of mode 17, and the authentication output method of mode 24.

On the other hand, to achieve the above advantage, the network device of mode 6 is a network device for performing an output operation on the basis of output data, and comprises an output data receiving unit for receiving the output data, an output data transfer unit for transferring the output data received in the output data receiving unit to an output data storing device, a certification information generating unit for generating certification information used to certify a utilization competency of the output data, a certification information transmitting unit for transmitting the certification information generated in the certification information generating unit to a predetermined output destination, a certification information acquiring unit for acquiring the certification information, a utilization competency judging unit for judging whether there is the utilization competency of the output data on the basis of the certification information acquired in the certification information acquiring unit, an output data acquiring unit for acquiring the output data from the output data storing device, and an output unit for performing the output operation on the basis of the output data acquired in the output data acquiring unit; and

the output data acquiring unit acquires the output data from the output data storing device when the utilization competency judging unit judges that there is the utilization competency of the output data.

In accordance with such a construction, an action equal to that in the network device in the authentication output system of mode 1 is obtained. Accordingly, an effect equal to that in the authentication output system of mode 1 is obtained.

Further, in the network device of mode 6, the network device of mode 7 is characterized in that the output data transfer unit transfers the output data received by the output data receiving unit and device identification information for discriminating the network device to the output data storing device; and

the output data acquiring unit transmits the acquiring request of the output data including the device identification information to the output data storing device.

In accordance with such a construction, an action equal to that in the network device in the authentication output system of mode 2 is obtained. Accordingly, an effect equal to that in the authentication output system of mode 2 is obtained.

Further, in the network device of one of modes 6 and 7, the network device of mode 8 is characterized in that the network device further has output data dividing unit for dividing the output data received in the output data receiving unit,

the output data transfer unit transfers the divisional output data divided in the output data dividing unit to the plural output data storing devices, and

the output data acquiring unit acquires the divisional output data from the plural output data storing devices, and constructs the output data on the basis of the acquired plural divisional output data.

In accordance with such a construction, an action equal to that in the network device in the authentication output system of mode 3 is obtained. Accordingly, an effect equal to that in the authentication output system of mode 3 is obtained.

Further, in the network device of one of modes 6 and 7, the network device of mode 9 is characterized in that the output data transfer unit transfers the output data received in the output data receiving unit to each of the plural output data storing devices, and

the output data acquiring unit acquires the output data from one of the plural output data storing devices.

In accordance with such a construction, an action equal to that in the network device in the authentication output system of mode 4 is obtained. Accordingly, an effect equal to that in the authentication output system of mode 4 is obtained.

Further, in the network device of one of modes 6 to 9, the network device of mode 10 is characterized in that the network device further has output data storing device selecting unit for selecting an output data storing device from the plural output data storing devices on the basis of status information showing ability or a resource state of the output data storing device, and

the output data transfer unit transfers the output data to the output data storing device selected by the output data storing device selecting unit.

In accordance with such a construction, an action equal to that in the network device in the authentication output system of mode 5 is obtained. Accordingly, an effect equal to that in the authentication output system of mode 5 is obtained.

On the other hand, to achieve the above advantage, the device utilizing apparatus of mode 11 is a device utilizing apparatus for utilizing a network device, and comprises:

an output data generating unit for generating the output data, a generating output data transmitting unit for transmitting the output data generated in the output data generating unit to the network device, an output data memory unit, output data storing unit for storing the output data transferred from the network device to the output data memory unit, and an output data transmitting unit for transmitting the output data of the output data memory unit to the network device in accordance with an acquiring request from the network device.

In accordance with such a construction, the output data are generated by the output data generating unit, and the generated output data are transmitted to the network device by the generating output data transmitting unit. Further, an action equal to that in the output data storing device in the authentication output system of mode 1 is obtained.

Thus, an effect equal to that in the authentication output system of mode 1 is obtained.

Further, the device utilizing apparatus of mode 12 is a device utilizing apparatus for utilizing a network device, and comprises:

an output data generating unit for generating the output data, a generating output data transmitting unit for transmitting the output data generated in the output data generating unit to the network device, certification information receiving unit for receiving certification information transmitted from the network device, and a certification information output unit for outputting the certification information received in the certification information receiving unit.

In accordance with such a construction, the output data are generated by the output data generating unit, and the generated output data are transmitted to the network device by the generating output data transmitting unit. When the network device in the authentication output system of mode 1 sets the device utilizing apparatus as a predetermined output destination and the certification information is received by the certification information receiving unit, the received certification information is outputted by the certification information output unit.

Thus, an effect equal to that in the authentication output system of mode 1 is obtained.

On the other hand, to achieve the above advantage, the output control program of mode 13 is an output control program for performing an output operation on the basis of output data, and includes a program for making a computer execute processing constructed by an output data receiving step for receiving the output data, an output data transfer step for transferring the output data received in the output data receiving step to an output data storing device, a certification information generating step for generating certification information used to certify a utilization competency of the output data, a certification information transmitting step for transmitting the certification information generated in the certification information generating step to a predetermined output destination, a certification information acquiring step for acquiring the certification information, a utilization competency judging step for judging whether there is the utilization competency of the output data on the basis of the certification information acquired in the certification information acquiring step, an output data acquiring step for acquiring the output data from the output data storing device, and an output step for performing the output operation on the basis of the output data acquired in the output data acquiring step; and

the output data are acquired from the output data storing device in the output data acquiring step when it is judged in the utilization competency judging step that there is the utilization competency of the output data.

In accordance with such a construction, the program is read by the computer. When the computer executes the processing in accordance with the read program, an action and an effect equal to those in the network device of mode 6 are obtained.

Here, the certification information acquiring step may be set to any mode if the certification information is acquired. For example, the certification information may be inputted from an input device, or the like, and the certification information may be gained or received from an external terminal, or the like. Further, the certification information may also be read from a memory device, a memory medium, or the like. Accordingly, the acquisition includes at least input, gaining, reception and reading-out. Hereinafter, the same contents are set in the authentication output system of mode 20.

The output step may be set to any mode if the output operation is performed on the basis of the output data. For example, the output step includes a printing step for performing a printing operation on the basis of print data, a display step for performing a display operation on the basis of display data, or a sound output step for outputting a voice on the basis of voice data. For example, the display operation is performed by a projector and an LCD device as the display step. Hereinafter, the same contents are set in the authentication output system of mode 20.

In the output control program of mode 13, the output control program of mode 14 is characterized in that the output data received in the output data receiving step and device identification information for discriminating the network device are transferred to the output data storing device in the output data transfer step; and

the acquiring request of the output data including the device identification information is transmitted to the output data storing device in the output data acquiring step.

In accordance with such a construction, a program is read by the computer. When the computer executes processing in accordance with the read program, an action and an effect equal to those in the network device of mode 7 are obtained.

Further, in the output control program of one of modes 13 and 14, the output control program of mode 15 is characterized in that this output control program further includes a program for making a computer execute processing constructed by an output data dividing step for dividing the output data received in the output data receiving step,

the divisional output data divided in the output data dividing step is transferred to the plural output data storing devices in the output data transfer step, and

the divisional output data are acquired from the plural output data storing devices, and the output data are constructed on the basis of the acquired plural divisional output data in the output data acquiring step.

In accordance with such a construction, a program is read by the computer. When the computer executes processing in accordance with the read program, an action and an effect equal to those in the network device of mode 8 are obtained.

Further, in the output control program of one of modes 13 and 14, the output control program of mode 16 is characterized in that the output data received in the output data receiving step are transferred to each of the plural output data storing devices in the output data transfer step, and

the output data are acquired from one of the plural output data storing devices in the output data acquiring step.

In accordance with such a construction, a program is read by the computer. When the computer executes processing in accordance with the read program, an action and an effect equal to those in the network device of mode 9 are obtained.

Further, in the output control program of one of modes 13 to 16, the output control program of mode 17 is characterized in that this output control program further includes a program for making a computer execute processing constructed by an output data storing device selecting step for selecting an output data storing device from the plural output data storing devices on the basis of status information showing ability or a resource state of the output data storing device, and

the output data are transferred to the output data storing device selected in the output data storing device selecting step in the output data transfer step.

In accordance with such a construction, a program is read by the computer. When the computer executes processing in accordance with the read program, an action and an effect equal to those in the network device of mode 10 are obtained.

On the other hand, to achieve the above advantage, the output request program of mode 18 is an output request program for requesting an output from a network device, and including:

a program for making a computer execute processing constructed by an output data generating step for generating the output data, a generating output data transmitting step for transmitting the output data generated in the output data generating step to the network device, an output data storing step for storing the output data transferred from the network device to output data memory unit, and an output data transmitting step for transmitting the output data of the output data memory unit to the network device in accordance with an acquiring request from the network device.

In accordance with such a construction, a program is read by the computer. When the computer executes processing in accordance with the read program, an action and an effect equal to those in the device utilizing apparatus of mode 11 are obtained.

Further, the output request program of mode 19 is an output request program for requesting an output from a network device, and includes:

a program for making a computer execute processing constructed by an output data generating step for generating the output data, a generating output data transmitting step for transmitting the output data generated in the output data generating step to the network device, a certification information receiving step for receiving certification information transmitted from the network device, and a certification information output step for outputting the certification information received in the certification information receiving step.

In accordance with such a construction, a program is read by the computer. When the computer executes processing in accordance with the read program, an action and an effect equal to those in the device utilizing apparatus of mode 12 are obtained.

On the other hand, to achieve the above advantage, the authentication output method of mode 20 is an authentication output method in which a network device for performing an output operation on the basis of output data and an output data storing device for storing the output data are communicably connected, and the output operation is performed by the network device via authentication,

wherein, with respect to the network device, the authentication output method includes an output data receiving step for receiving the output data, an output data transfer step for transferring the output data received in the output data receiving step to the output data storing device, a certification information generating step for generating certification information used to certify a utilization competency of the output data, and a certification information transmitting step for transmitting the certification information generated in the certification information generating step to a predetermined output destination;

the authentication output method includes an output data storing step for storing the output data transferred from the network device to an output data memory unit with respect to the output data storing device;

with respect to the network device, the authentication output method further includes:

a certification information acquiring step for acquiring the certification information;

a utilization competency judging step for judging whether there is a utilization competency of the output data on the basis of the certification information acquired in the certification information acquiring step; and

an output data acquiring step for acquiring the output data from the output data storing device when it is judged in the utilization competency judging step that there is the utilization competency of the output data;

the authentication output method further includes an output data transmitting step for transmitting the output data of the output data memory unit to the network device in accordance with an acquiring request from the network device with respect to the output data storing device; and

the authentication output method further includes an output step for performing the output operation on the basis of the output data acquired in the output data acquiring step with respect to the network device.

Thus, an effect equal to that in the authentication output system of mode 1 is obtained.

Further, in the authentication output method of mode 20, the authentication output method of mode 21 is characterized in that the output data received in the output data receiving step and device identification information for discriminating the network device are transferred to the output data storing device in the output data transfer step;

the output data transferred from the network device and the device identification information are correspondingly set and are stored to the output data memory unit in the output data storing step;

the acquiring request of the output data including the device identification information is transmitted to the output data storing device in the output data acquiring step; and

the output data corresponding to the device identification information included in the acquiring request are read from the output data memory unit, and the read output data are transmitted to the network device specified by this device identification information in the output data transmitting step.

Thus, an effect equal to that in the authentication output system of mode 2 is obtained.

Further, in the authentication output method of one of modes 20 and 21, the authentication output method of mode 22 is characterized in that the authentication output method further includes an output data dividing step for dividing the output data received in the output data receiving step,

the divisional output data divided in the output data dividing step are transferred to the plural output data storing devices in the output data transfer step, and

the divisional output data are acquired from the plural output data storing devices, and the output data are constructed on the basis of the acquired plural divisional output data in the output data acquiring step.

Thus, an effect equal to that in the authentication output system of mode 3 is obtained.

Further, in the authentication output method of one of modes 20 and 21, the authentication output method of mode 23 is characterized in that the output data received in the output data receiving step are transferred to each of the plural output data storing devices in the output data transfer step, and

the output data are acquired from one of the plural output data storing devices in the output data acquiring step.

Thus, an effect equal to that in the authentication output system of mode 4 is obtained.

Further, in the authentication output method of one of modes 20 to 23, the authentication output method of mode 24 is characterized in that the authentication output method further includes an output data storing device selecting step for selecting an output data storing device from the plural output data storing devices on the basis of status information showing ability or a resource state of the output data storing device with respect to the network device, and

the output data are transferred to the output data storing device selected in the output data storing device selecting step in the output data transfer step.

Thus, an effect equal to that in the authentication output system of mode 5 is obtained.

### BRIEF DESCRIPTION OF THE DRAWINGS

Embodiments of the invention will be described with reference to the accompanying drawings, wherein like numbers reference like elements, and wherein:

FIG. 1 is a functional block diagram schematically showing the function of a network system;

FIG. 2 is a block diagram showing the hardware construction of a host terminal 100;

FIG. 3 is a flow chart showing print request processing;

FIG. 4 is a block diagram showing the hardware construction of a network printer 200;

FIG. 5 is a table showing a data structure of a certification information managing table 400;

FIG. 6 is a flow chart showing print request reception processing;

FIG. 7 is a flow chart showing data server selection processing;

FIG. 8 is a table showing a data structure of status information;

FIG. 9 is a flow chart showing print control processing;

FIG. 10 is a block diagram showing the hardware construction of a data server 300;

FIG. 11 is a table showing a data structure of a print data managing table 420;

FIG. 12 is a flow chart showing print data registration processing;

FIG. 13 is a flow chart showing print data transmission processing; and

FIG. 14 is a flow chart showing status information transmission processing.

### DESCRIPTION OF THE EMBODIMENTS

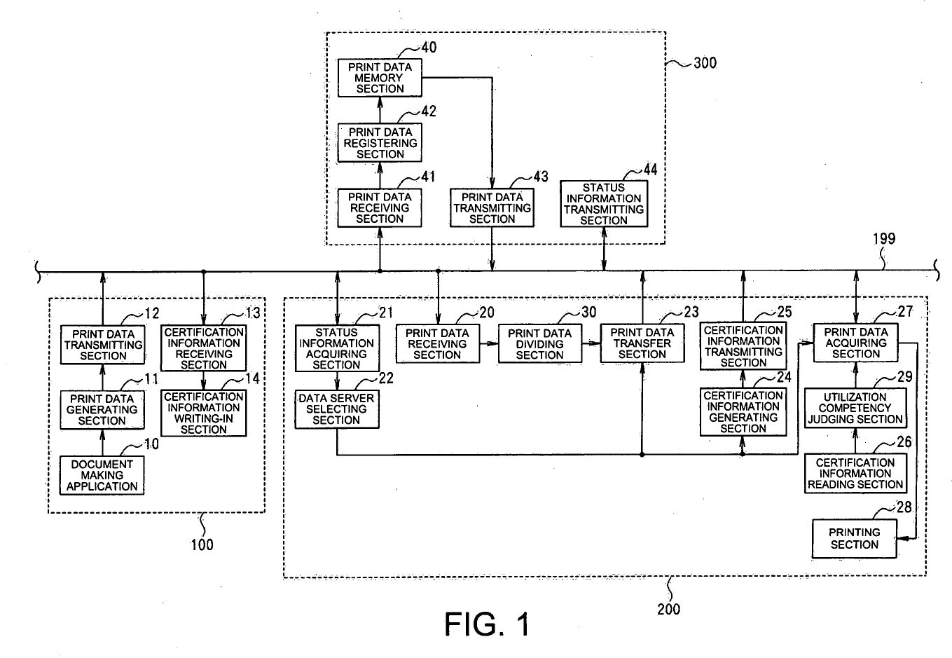

Embodiments of the invention will now be explained with reference to the drawings. FIGS. 1 to 14 are views showing the embodiments of an authentication output system, a network device, a device utilizing apparatus, an output control program, an output request program and an authentication output method in accordance with the invention.

In the present embodiments, the authentication output system, the network device, the device utilizing apparatus, the output control program, the output request program and the authentication output method are applied to a case in which printing is performed by a network printer 200 utilizing an authentication card as shown in FIG. 1.

First, the function of a network system applying the invention thereto will be schematically explained with reference to FIG. 1.

FIG. 1 is a functional block diagram schematically showing the function of the network system.

As shown in FIG. 1, a host terminal 100, plural network printers 200 and a data server 300 are connected to a network 199.

The host terminal 100 is constructed by arranging a document making application 10 able to edit document data by a user, a print data generating section 11 for generating print data on the basis of the document data edited in the document making application 10, a print data transmitting section 12 for transmitting print data generated in the print data generating section 11 to the network printer 200, a certification information receiving section 13 for receiving certification information, and a certification information writing-in section 14 for writing the certification information received in the certification information receiving section 13 into an authentication card.

The network printer 200 is constructed by arranging a print data receiving section 20 for receiving the print data, a status information acquiring section 21 for acquiring status information showing ability and a resource state of the data server 300 from the data server 300, a data server selecting section 22 for selecting plural storing destinations from plural data servers 300 on the basis of the status information acquired in the status information acquiring section 21, a print data dividing section 30 for dividing the print data received by the print data receiving section 20, and a print data transfer section 23 for transferring the print data to the data server 300.

The print data transfer section 23 transfers the divisional print data divided by the print data dividing section 30 to the data server 300 selected in the data server selecting section 22.

The network printer 200 is further constructed by arranging a certification information generating section 24 for generating the certification information on the basis of a server name of the data server 300 selected in the data server selecting section 22, a certification information transmitting section 25 for transmitting the certification information generated in the certification information generating section 24 to the host terminal 100, a certification information reading section 26 for reading the certification information from the authentication card constructed by an IC card, or the like, a utilization competency judging section 29 for judging whether there is a utilization competency of the print data on the basis of the certification information read in the certification information reading section 26, a print data acquiring section 27 for acquiring the print data from the data server 300, and a printing section 28 for performing a printing operation on the basis of the print data acquired in the print data acquiring section 27.

The print data acquiring section 27 acquires the divisional print data from the data server 300 selected in the data server selecting section 22, and constructs the print data on the basis of the acquired plural divisional print data when the utilization competency judging section 29 judges that there is a utilization competency of the print data.

The data server 300 is constructed by arranging a print data memory section 40, a print data receiving section 41 for receiving the print data transferred from the network printer 200, a print data storing section 42 for storing the print data received in the print data receiving section 41 to the print data memory section 40, a print data transmitting section 43 for transmitting the print data of the print data memory section 40 to the network printer 200 in accordance with an acquiring request from the network printer 200, and a status information transmitting section 44 for transmitting the status information in accordance with the acquiring request from the network printer 200.

The construction of the host terminal 100 will now be explained.

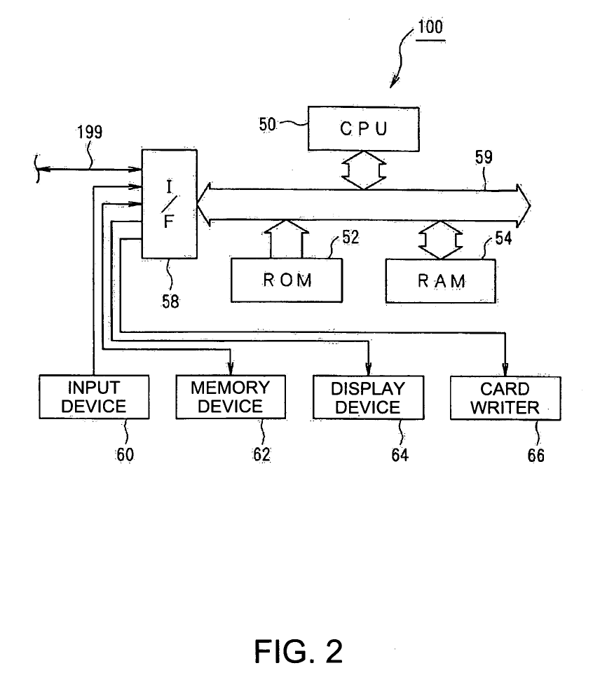

FIG. 2 is a block diagram showing the hardware construction of the host terminal 100.

As shown in FIG. 2, the host terminal 100 is constructed by a CPU 50 for controlling an arithmetic operation and the operation of the entire system on the basis of a control program, a ROM 52 for storing a control program of the CPU 50, or the like to a predetermined area in advance, a RAM 54 for storing data read out of the ROM 52, or the like and an arithmetic result required in an arithmetic process of the CPU 50, and an I/F 58 for mediating the input and output of data with respect to an external device. These elements are connected to each other by a bus 59 as a signal line for transferring data so as to transmit and receive data.

An input device 60 constructed by a keyboard, a mouse, or the like able to input data as a human interface, a memory device 62 for storing data, a table, or the like as a file, a display device 64 for displaying a screen on the basis of an image signal, a card writer 66 for writing the certification information into the inserted authentication card, and a signal line for connection to the network 199 are connected to the I/F 58 as an external device.

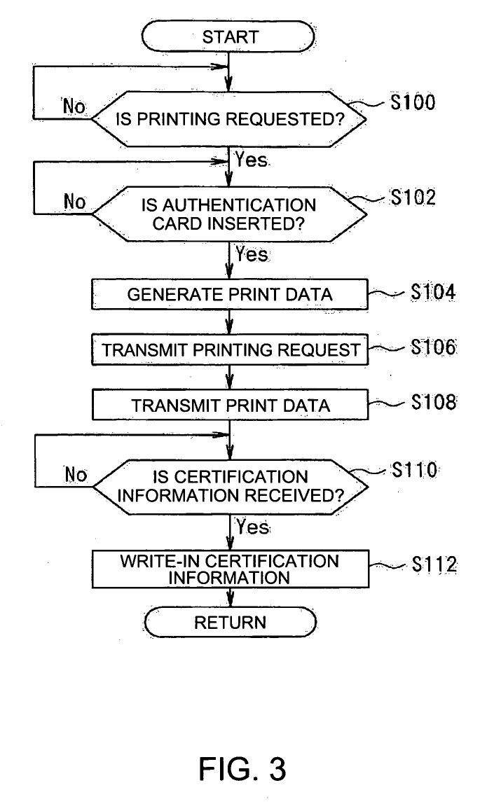

The CPU 50 is constructed by a micro processing unit, or the like, and starts a predetermined program stored to a predetermined area of the ROM 52, and executes print request processing shown in the flow chart of FIG. 3 in accordance with this program.

FIG. 3 is the flow chart showing the print request processing.

The print request processing is processing for requiring printing from the network printer 200. When the print request processing is executed in the CPU 50, it first proceeds to step S100 as shown in FIG. 3.

In step S100, it is judged whether printing is requested from the document making application 10. When it is judged that printing is requested (Yes), it proceeds to step S102. In contrast to this, when it is judged that no printing is requested (No), it waits in step S100 until the printing is requested.

In step S102, it is judged whether the authentication card is inserted into the card writer 66 or not. When it is judged that the authentication card is inserted (Yes), it proceeds to step S104. In contrast to this, when it is judged that no authentication card is inserted (No), it waits in step S102 until the authentication card is inserted.

In step S104, the print data are generated by a printer driver on the basis of document data edited in the document making application 10, and it proceeds to step S106. In this step, a print request is transmitted to the network printer 200, and it proceeds to step S108. In this step, the generated print data are transmitted to the network printer 200, and it proceeds to step S110.

In step S110, it is judged whether certification information is received or not. When it is judged that the certification information is received (Yes), it proceeds to step S112. In this step, the received certification information is written into the authentication card by the card writer 66, and the series of processings is terminated and it is returned to the original processing.

On the other hand, when it is judged in step S110 that no certification information is received (No), it waits in step S110 until the certification information is received.

The construction of the network printer 200 will now be explained.

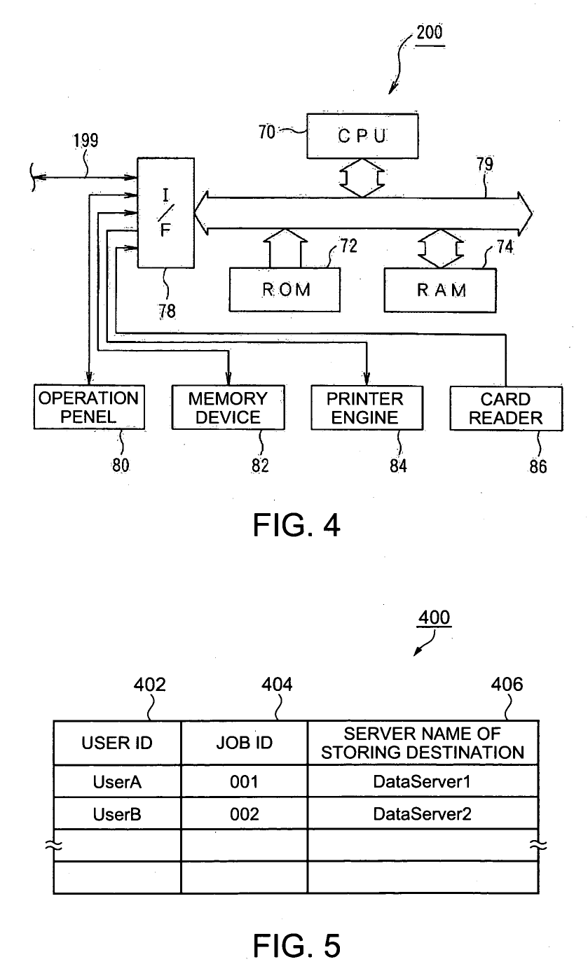

FIG. 4 is a block diagram showing the hardware construction of the network printer 200.

As shown in FIG. 4, the network printer 200 is constructed by a CPU 70 for controlling an arithmetic operation and the operation of the entire system on the basis of a control program, a ROM 72 for storing the control program of the CPU 70, or the like to a predetermined area in advance, a RAM 74 for storing data read out of the ROM 72, or the like and an arithmetic result required in an arithmetic process of the CPU 70, and an I/F 78 for mediating the input and output of data with respect to an external device. These elements are connected to each other by a bus 79 as a signal line for transferring data so as to transmit and receive data.

An operation panel 80 constructed by a touch panel, or the like able to input and display data as a human interface, a memory device 82 for storing data, a table, or the like as a file, a printer engine 84 constructed by a print head, a head driving, section and other mechanisms required in printing, a card reader 86 for reading the certification information from the inserted authentication card, and a signal line for connection to the network 199 are connected to the I/F 78 as an external device.

FIG. 5 is a table showing a data structure of a certification information managing table 400.

As shown in FIG. 5, the memory device 82 stores the certification information managing table 400 for managing the certification information.

One record is registered to the certification information managing table 400 every each print data. Each record is constructed by including a field 402 for registering a user ID, a field 404 for registering a job ID allocated with respect to the print data, and a field 406 for registering the name of the data server 300 as a storing destination of the print data.

In the example of FIG. 5, “UserA” as the user ID, “001”as the job ID and “DataServer1” as the server name of the storing destination are respectively registered to the record of a first stage. This shows that the certification information used to certify the utilization competency of print data 1 (which are print data specified by the job ID “001” and are similarly abbreviated hereinafter) is “UserA”, and the print data 1 are stored to the data server 300 of the server name “DataServer1”. The address of the data server 300 can be specified by the server name by utilizing a name server and other name solving methods.

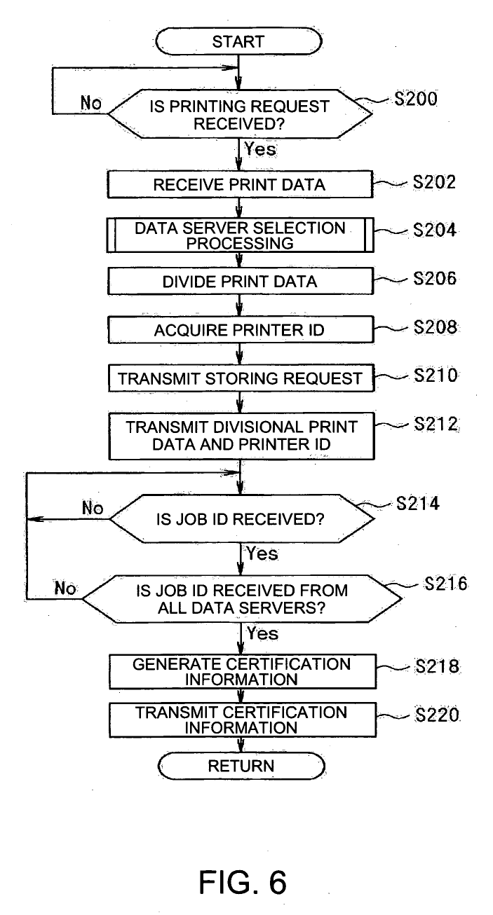

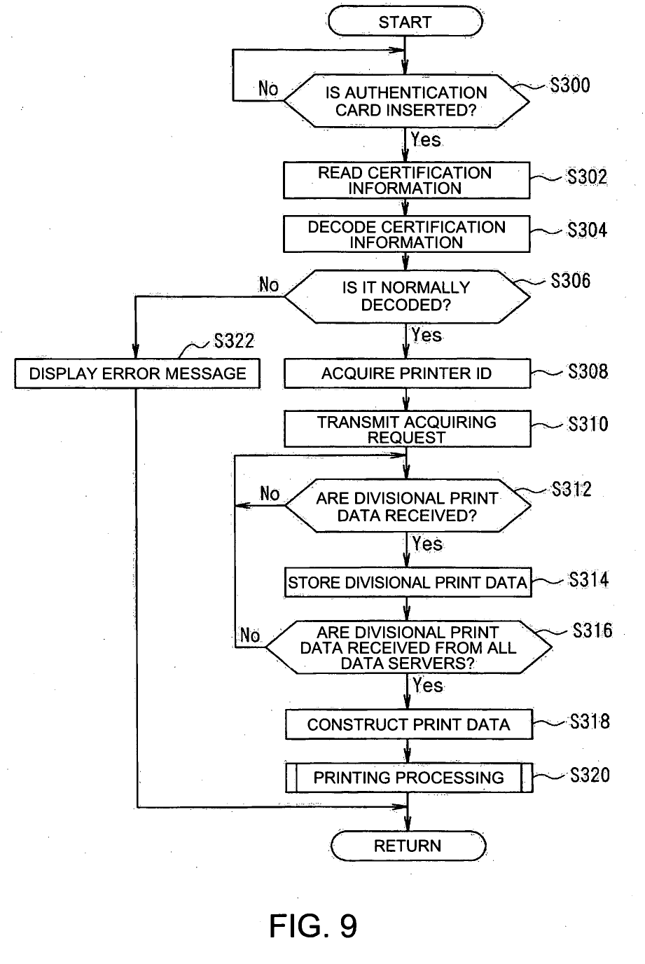

The CPU 70 is constructed by a micro processing unit, or the like, and starts a predetermined program stored to a predetermined area of the ROM 72, and executes each of print request reception processing and print control processing shown in the flow charts of FIGS. 6 and 9 in time division in accordance with this program.

The print request reception processing will first be explained in detail with reference to FIG. 6.

FIG. 6 is a flow chart showing the print request reception processing.

The print request reception processing is processing for receiving a print request from the host terminal 100. When the print request reception processing is executed in the CPU 70, it first proceeds to step S200 as shown in FIG. 6.

In step S200, it is judged whether a print request is received or not. When it is judged that the print request is received (Yes), it proceeds to step S202. In contrast to this, when it is judged that no print request is received (No), it waits in step S200 until the print request is received.

In step S202, print data are received and it proceeds to step S204. In this step, data server selection processing for selecting plural data servers 300 is executed, and it proceeds to step S206.

In step S206, the received print data are divided by the number of selected data servers 300 (hereinafter simply called the selection data server 300), and it proceeds to step S208. In this step, a printer ID allocated to the self network printer 200 is acquired and it proceeds to step S210.

In step S210, a storing request of the print data is transmitted to each selection data server 300, and it proceeds to step S212. In this step, the divided divisional print data and the acquired printer ID are transmitted to each selection data server 300, and it proceeds to step S214.

In step S214, it is judged whether a job ID is received or not. When it is judged that the job ID is received (Yes), it proceeds to step S216. In this step, it is judged whether the job ID is received from all the selection data servers 300 or not. When it is judged that the job ID is received from all the selection data servers 300 (Yes), it proceeds to step S218.

In step S218, the received job ID and the name of the selection data server 300 are coded by a predetermined coding algorithm (e.g., BASE64), and certification information is generated. It then proceeds to step S220, and the generated certification information is transmitted to the host terminal 100. Thus, the series of processings is terminated and it is returned to the original processing.

In contrast to this, when it is judged in step S216 that no job ID is received from one of the, data servers 300 (No), it proceeds to step S214.

On the other hand, when it is judged in step S214 that no job ID is received (No), it waits in step S214 until the job ID is received.

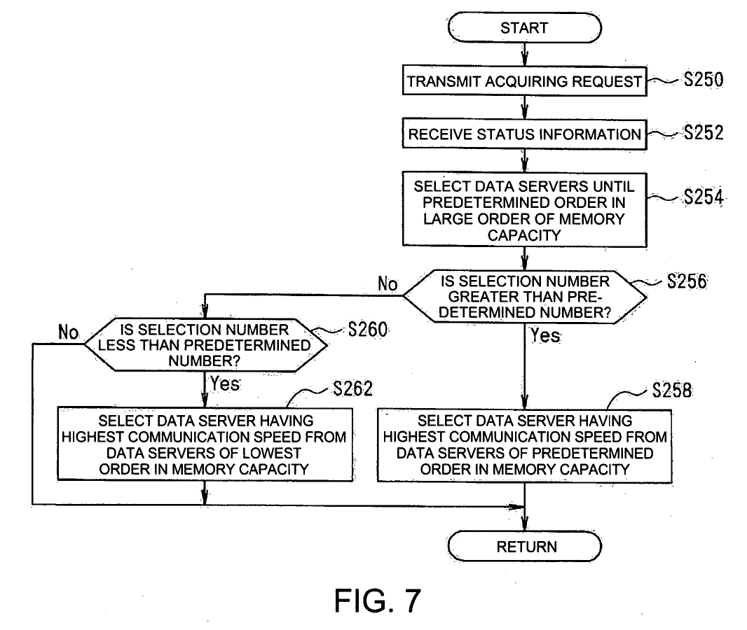

Next, the data server selection processing of step S204 will be explained in detail with reference to FIG. 7.

FIG. 7 is a flow chart showing the data server selection processing.

The data server selection processing is processing for selecting plural storing destinations from the plural data servers 300. When the data server selection processing is executed in step S204, it first proceeds to step S250 as shown in FIG. 7.

In step S250, an acquiring request of status information is transmitted to all the data servers 300, and it proceeds to step S252. In this step, the status information is received from all the data servers 300.

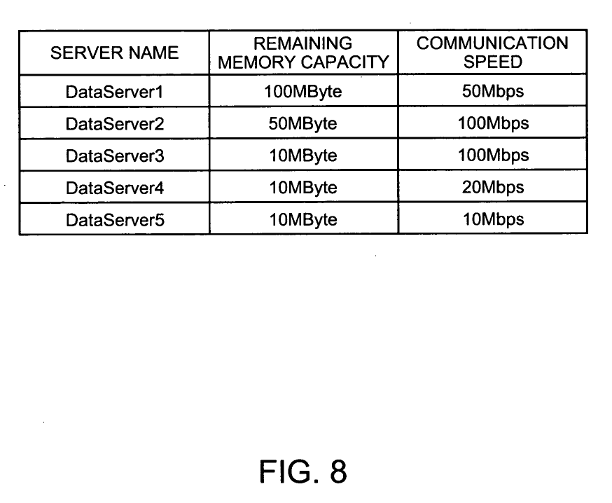

FIG. 8 is a table showing a data structure of the status information.

As shown in FIG. 8, the status information is constructed by including the name of the data server 300, the remaining memory capacity of a memory device 63 of the data server 300, and a communication speed with the network printer 200. In the example of FIG. 8, the status information is constructed by five records, but this example shows a list of the status information acquired from five data servers 300.

It is returned to FIG. 7 and it next proceeds to step S254. On the basis of the received status information, the data servers 300 until a predetermined order (e.g., third) in a large order of the remaining memory capacity of the memory device 63 are selected from the plural data servers 300. For example, when one data server 300 of 100 Mbytes, one data server 300 of 50 Mbytes and three data servers 300 of 10 Mbytes in the remaining memory capacity exist, these five data servers 300 are selected.

Next, it proceeds to step S256, and it is judged whether the number of selected data servers 300 is greater than a predetermined number (e.g., three) or not. When it is judged that the number of selected data servers 300 is greater than the above predetermined number (Yes), it proceeds to step S258. In this step, a data server 300 having a highest communication speed is selected from the data servers 300 of the above predetermined order in the remaining memory capacity of the memory device 63. For example, the five data servers 300 are selected in the above example. However, since there are three data servers 300 of 10 Mbytes in the remaining memory capacity, a data server 300 having the highest communication speed is selected from these three data servers 300. Thus, the number of selected data servers 300 is narrowed down to the above predetermined number.

When the processing of step S258 is terminated, the series of processings is terminated and it is returned to the original processing.

In contrast to this, when it is judged in step S256 that the number of selected data servers 300 is the above predetermined number or less (No), it proceeds to step S260. In this step, it is judged whether the number of selected data servers 300 is less than the above predetermined number or not. When it is judged that the number of selected data servers 300 is less than the above predetermined number (Yes), it proceeds to step S262. In this step, a data server 300 having the highest communication speed is selected from the data servers 300 in a smallest order of the remaining memory capacity of the memory device 63. A selecting method is similar to that in step S258. Thus, a deficient data server 300 is selected by addition, and the number of selected data servers 300 is set to the above predetermined number.

When the processing of step S262 is terminated, the series of processings is terminated and it is returned to the original processing.

The print control processing will now be explained in detail with reference to FIG. 9.

FIG. 9 is a flow chart showing the print control processing.

The print control processing is processing for performing a printing operation by reading the certification information from the authentication card. When the print control processing is executed in the CPU 70, it first proceeds to step S300 as shown in FIG. 9.

In step S300, it is judged whether the authentication card is inserted into the card reader 86 or not. When it is judged that the authentication card is inserted (Yes), it proceeds to step S302. In contrast to this, when it is judged that no authentication card is inserted (No), it waits in step S300 until the authentication card is inserted.

In step S302, the certification information is read from the authentication card by the card reader 86, and it proceeds to step S304. In this step, the read certification information is decoded by a decoding algorithm corresponding to the above coding algorithm, and it proceeds to step S306.

In step S306, it is judged whether appropriate job ID and server name are obtained by decoding the certification information or not. When it is judged that the appropriate job ID and server name are obtained (Yes), it proceeds to step S308. In this step, a printer ID allocated to the self network printer 200 is acquired, and it proceeds to step S310. In this step, an acquiring request of print data including the acquired printer ID and the job ID obtained by the decoding is transmitted to each selection data server 300 specified by the server name obtained by the decoding, and it proceeds to step S312.

In step S312, it is judged whether the divisional print data are received or not. When it is judged that the divisional print data are received (Yes), it proceeds to step S314. In this step, the received divisional print data are stored to the memory device 82, and it proceeds to step S316. In this step, it is judged whether the divisional print data are received from all the selection data servers 300 or not. When it is judged that the divisional print data are received from all the selection data servers 300 (Yes), it proceeds to step S318.

In step S318, on the basis of the divisional print data of the memory device 82, the print data before the division are constructed by arranging and connecting these divisional data in the original order, and it proceeds to step S320. In this step, the printing operation is performed by the printer engine 84 on the basis of the constructed print data, and the series of processings is terminated and it is returned to the original processing.

In contrast to this, when it is judged in step S316 that no divisional print data are received from one of the selection data servers 300 (No), it proceeds to step S312.

When it is judged in step S312 that no divisional print data are received (No), it waits in step S312 until the divisional print data are received.

On the other hand, when it is judged in step S306 that no appropriate job ID and server name are obtained (No), it proceeds to step S322 and an error message is displayed in the operation panel 80, and the series of processings is terminated and it is returned to the original processing.

The construction of the data server 300 will now be explained.

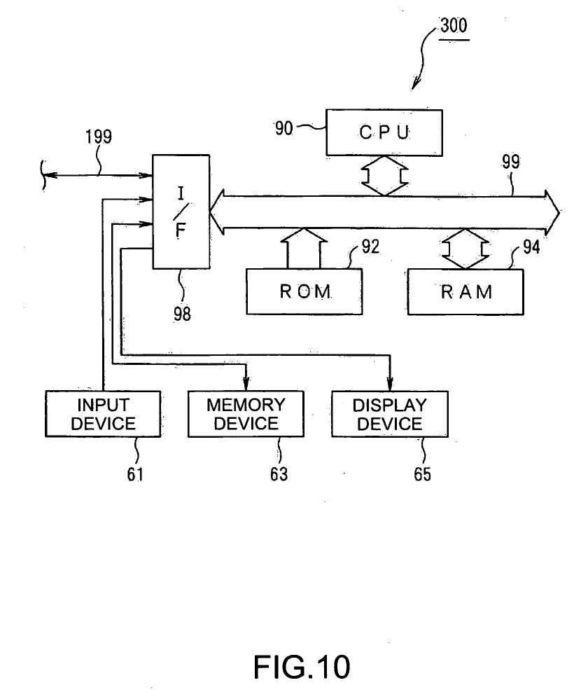

FIG. 10 is a block diagram showing the hardware construction of the data server 300.

As shown in FIG. 10, the data server 300 is constructed by a CPU 90 for controlling an arithmetic operation and the operation of the entire system on the basis of a control program, a ROM 92 for storing the control program of the CPU 90, or the like to a predetermined area in advance, a RAM 94 for storing data read out of the ROM 92, or the like and an arithmetic result required in an arithmetic process of the CPU 90, and an I/F 98 for mediating the input and output of data with respect to an external device. These elements are connected to each other by a bus 99 as a signal line for transferring data so as to transmit and receive data.

An input device 61 constructed by a keyboard, a mouse, or the like able to input data as a human interface, a memory device 63 for storing data, a table, or the like as a file, a display device 65 for displaying a screen on the basis of an image signal, and a signal line for connection to the network 199 are connected to the I/F 98 as an external device.

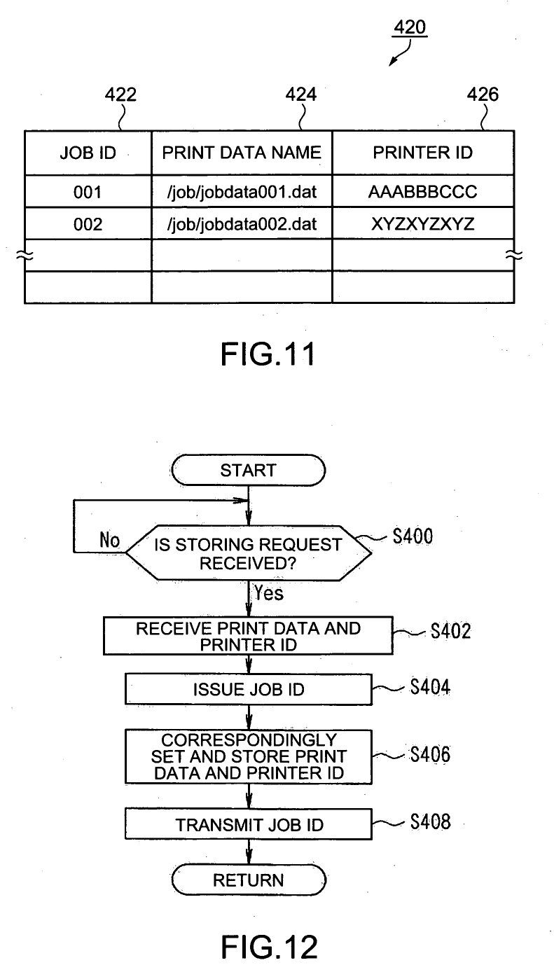

FIG. 11 is a table showing a data structure of a print data managing table 420.

The memory device 63 stores print data and stores the print data managing table 420 for managing the print data as shown in FIG. 11.

One record is registered to the print data managing table 420 every each print data. Each record is constructed by including a field 422 for registering the job ID, a field 424 for registering a file name of the print data, and a field 426 for registering the printer ID.

In the example of FIG. 11, “001” as the job ID, “/job/jobdata001.dat” as the file name, and “AAABBBCCC” as the printer ID are respectively registered to the record of a first stage. This shows that print data 1 are “/job/jobdata001.dat” in the file name and are transferred from the network printer 200 specified by the printer ID “AAABBBCCC”.

The CPU 90 is constructed by a micro processing unit, or the like, and starts a predetermined program stored to a predetermined area of the ROM 92, and executes each of print data registration processing, print data transmission processing and status information transmission processing shown in the flow charts of FIGS. 12 to 14 in time division in accordance with this program.

The print data registration processing will first be explained in detail with reference to FIG. 12.

FIG. 12 is a flow chart showing the print data registration processing.

The print data registration processing is processing for storing print data to the memory device 63 in accordance with a storing request from the network printer 200. When the print data registration processing is executed in the CPU 90, it first proceeds to step S400 as shown in FIG. 12.

In step S400, it is judged whether the storing request of the print data is received or not. When it is judged that the storing request is received (Yes), it proceeds to step S402. In contrast to this, when it is judged that no storing request is received (No), it waits in step S400 until the storing request is received.

In step S402, the print data and the printer ID are received and it proceeds to step S404. In this step, a job ID is issued with respect to the received print data, and it proceeds to step S406.

In step S406, the received print data are stored to the memory device 63, and the issued job ID, the file name of the print data and the received printer ID are correspondingly set and are registered to the print data managing table 420. It then proceeds to step S408, and the issued job ID is transmitted to the network printer 200 of a request source, and the series of processings is terminated and it is returned to the original processing.

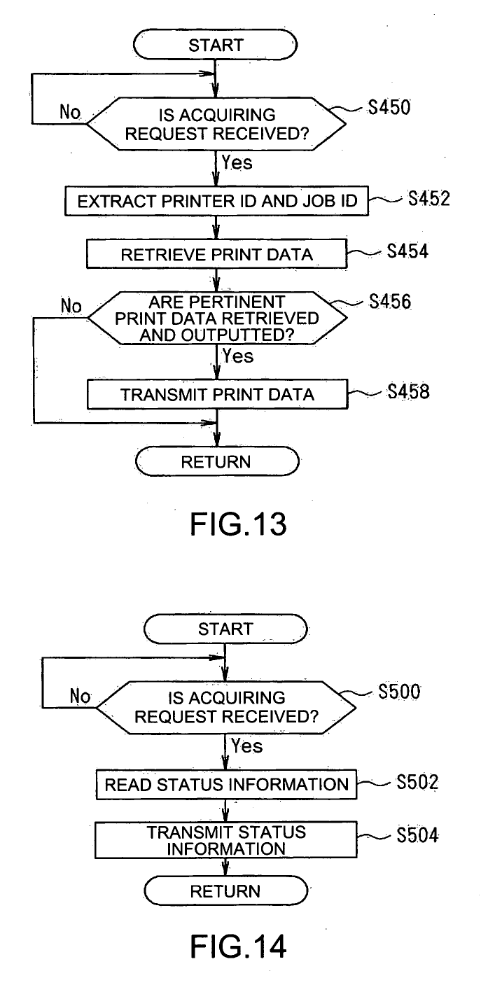

The print data transmission processing will now be explained in detail with reference to FIG. 13.

FIG. 13 is a flow chart showing the print data transmission processing.

The print data transmission processing is processing for transmitting the print data of the memory device 63 in accordance with an acquiring request from the network printer 200. When the print data transmission processing is executed in the CPU 90, it first proceeds to step S450 as shown in FIG. 13.

In step S450, it is judged whether an acquiring request of the print data is received or not. When it is judged that the acquiring request is received (Yes), it proceeds to step S425. In contrast to this, when it is judged that no acquiring request is received (No), it waits in step S450 until the acquiring request is received.

In step S452, the printer ID and the job ID are extracted from the received acquiring request, and it proceeds to step S454. In this step, print data corresponding to the extracted printer ID and job ID are retrieved from the memory device 63 with reference to the print data managing table 420, and it proceeds to step S456.

In step S456, it is judged whether the pertinent print data are retrieved and outputted or not. When it is judged that the pertinent print data are retrieved and outputted (Yes), it proceeds to step S458. In this step, the retrieved and outputted print data are transmitted to the network printer 200 specified by the extracted printer ID, and the series of processings is terminated and it is returned to the original processing.

In contrast to this, when it is judged in step S456 that no pertinent print data are retrieved and outputted (No), the series of processings is terminated and it is returned to the original processing.

The status information transmission processing will now be explained in detail with reference to FIG. 14.

FIG. 14 is a flow chart showing the status information transmission processing.

When the status information transmission processing is executed in the CPU 90, it first proceeds to step S500 as shown in FIG. 14.

In step S500, it is judged whether an acquiring request of the status information is received or not. When it is judged that the acquiring request is received (Yes), it proceeds to step S502. In contrast to this, when it is judged that no acquiring request is received (No), it waits in step S500 until the acquiring request is received.

In step S502, the status information of the self data server 300 is acquired, and it proceeds to step S504. In this step, the acquired status information is transmitted to the network printer 200 of a request source, and the series of processings is terminated and it is returned to the original processing.

The operation of this embodiment will now be explained.

A user edits document data by utilizing the document making application 10 in the host terminal 100, and inserts an authentication card into the card writer 66, and requests printing.

In the host terminal 100, when printing is requested, print data are generated on the basis of the document data via steps S104 to S108. The generated print data are transmitted to the network printer 200 together with the print request.

In the network printer 200, the print data are received via steps. S202, S250 when the print request is received. The acquiring request of the status information is transmitted to all the data servers 300.

In the data server 300, when the acquiring request of the status information is received, the self status information is acquired via steps S502, S504. The acquired status information is transmitted to the network printer 200 of a request source.

In the network printer 200, when the status information is received from all the data servers 300, plural storing destinations are selected from the plural data servers 300 on the basis of the received status information via steps S254 to S262. The received print data are then divided via steps S206 to S212, and the self printer ID is acquired. The divided divisional print data and the acquired printer ID are transmitted to each selection data server 300 together with a storing request.

In the data server 300, when the storing request is received, the divisional print data and the printer ID are received via steps S402 to S406. A job ID is issued with respect to the received divisional print data, and the received divisional print data are stored to the memory device 63. The issued job ID, a file name of the divisional print data and the received printer ID are correspondingly set, and are registered to the print data managing table 420. The issued job ID is then transmitted to the network printer 200 of a request source via step S408.

In the network printer 200, when the job ID is received from all the selection data servers 300, the received job ID and the name of the selection data server 300 are coded and certification information is generated via steps S218, S220. The generated certification information is transmitted to the host terminal 100.

In the host terminal 100, when the certification information is received, the received certification information is written into an authentication card by the card writer 66 via step S112.

Next, a user goes to the place of the network printer 200, and inserts the authentication card recording the certification information into the card reader 86.

In the network printer 200, when the authentication card is inserted into the card reader 86, the certification information is read from the authentication card by the card reader 86 via steps S302 to S306, and the read certification information is decoded. It is then judged whether appropriate job ID and server name are obtained by the decoding or not. When the user requests the printing by a normal procedure, the appropriate job ID and server name ought to be obtained. Accordingly, the self printer ID is acquired via steps S308, S310, and an acquiring request including the acquired printer ID and the job ID obtained by the decoding is transmitted to each selection data server 300 specified by the server name obtained by the decoding.

In the data server 300, when the acquiring request is received, the printer ID and the job ID are extracted from the received acquiring request via steps S452, S454. The divisional print data corresponding to the extracted printer ID and job ID are retrieved from the memory device 63 with reference to the print data managing table 420. Since the corresponding divisional print data ought to be registered to the data server 300, the divisional print data can be retrieved and outputted. When the divisional print data are retrieved and outputted, the retrieved and outputted divisional print data are transmitted to the network printer 200 specified by the extracted printer ID via step S458.

In the network printer 200, when the divisional print data are received, the received divisional print data are stored to the memory device 82 via step S314. When the divisional print data are received from all the selection data servers 300, the print data before the division are constructed on the basis of the divisional print data of the memory device 82 via steps S318, S320. Printing is then performed by the printer engine 84 on the basis of the constructed divisional print data.

When an authentication card recording the certification information except for normal certification information is used, no appropriate job ID or server name is obtained even by decoding the certification information in the network printer 200. Accordingly, an error message is displayed in the operation panel 80 via step S322.

Thus, in this embodiment, when the network printer 200 receives print data, the network printer 200 transfers the received print data to the data server 300, and generates and transmits the certification information to the host terminal 100. When the authentication card is given, the network printer 200 reads the certification information from the given authentication card. When the network printer 200 judges that there is a utilization competency of the print data on the basis of the read certification information, the network printer 200 acquires the print data from the data server 300 and performs the printing on the basis of the acquired print data.

Thus, since the certification information is generated in the network printer 200, it is not necessary to add a special program to the host terminal 100 so that the burden of a user is reduced. Further, since the print data are stored to the external data server 300 instead of the network printer 200, a large amount of print data can be set to be standby in comparison with the conventional case. Accordingly, when many print requests are simultaneously generated, the occurrence of no printing states can be reduced in comparison with the conventional case. Further, since the print data are acquired from the data server 300 having a transfer case of the print data, connection is reliable and the print data can be comparatively reliably acquired, and the occurrence of no printing events can be further reduced. Further, since the user can obtain the certification information in the host terminal 100, the certification information is easily obtained.

Further, in this embodiment, the network printer 200 transfers the received print data and printer ID to the data server 300, and transmits an acquiring request including the printer ID to the data server 300 and acquires the print data. The data server 300 correspondingly sets and stores the print data and the printer ID transferred from the network printer 200 to the memory device 63. When the acquiring request of the print data is received, the network printer 200 reads the print data corresponding to the printer ID included in the acquiring request from the memory device 63, and transmits the read print data to the network printer 200 specified by this printer ID.

Thus, in the data server 300, the print data transferred from the network printer 200 are comparatively reliably provided to this network printer 200. Accordingly, it is possible to reduce a possibility that the print data are utilized in another network printer 200 not intended by the user.

Further, in this embodiment, the network printer 200 divides the received print data and transfers the divided divisional print data to the plural data servers 300. When the network printer 200 judges that there is a utilization competency of the print data, the network printer 200 acquires the divisional print data from the plural data servers 300 and constructs the print data on the basis of the acquired plural divisional print data.

Thus, since the print data are divided and stored to the plural data servers 300, it is possible to reduce a possibility that the print data are concentrated onto one data server 300 and its memory capacity is suppressed.

Further, in this embodiment, the network printer 200 selects a storing destination from the plural data servers 300 on the basis of the status information showing ability and a resource state of the data server 300, and transfers the print data to the selection data server 300.

Thus, since the data server 300 is selected in consideration of the ability and the resource state of the data server 300, the print data can be efficiently transferred, stored and acquired.

In the above embodiment, the host terminal 100 corresponds to the device utilizing apparatus of mode 12, and the print data generating section 11 and step S104 correspond to an output data generating unit of mode 12. Step S104 corresponds to the output data generating step of mode 19, and the print data transmitting section 12, the I/F 58 and step S108 correspond to the output data transmitting unit of mode 12. Further, step S108 corresponds to the generating output data transmitting step of mode 19, and the certification information receiving section 13, the I/F 58 and step S110 correspond to the certification information receiving unit of mode 12. Step S110 corresponds to the certification information receiving step of mode 19.

Further, in the above embodiment, the certification information writing-in section 14, the card writer 66 and step S112 correspond to the certification information output unit of mode 12, and step S112 corresponds to the certification information output step of mode 19. The network printer 200 corresponds to the network devices of modes 1 to 3, 5 to 8, 10, 12, 14, 19 to 21 or 24. Further, the print data receiving section 20, the I/F 78 and step S202 correspond to the output data receiving unit of modes 1 to 3, 6 to 8, and step S202 corresponds to the output data receiving steps of modes 13 to 15, 20 to 22. The data server selecting section 22 and step S204 correspond to the output data storing device selecting unit of mode 5 or 10.

Further, in the above embodiment, step S204 corresponds to the output data storing device selecting step of mode 17 or 24, and the print data dividing section 30 and step S206 correspond to the output data dividing step of mode 3 or 8. Step S206 corresponds to the output data dividing step of mode 15 or 22. Further, the print data transfer section 23, the I/F 78 and steps S208 to S212 correspond to the output data transfer unit of modes 1 to 3, 5 to 8 or 10, and steps S208 to S212 correspond to the output data transfer steps of modes 13 to 15, 17, 20 to 22 or 24.

Further, in the above embodiment, the certification information generating section 24 and step S218 correspond to the certification information generating unit of mode 1 or 6, and step S218 corresponds to the certification information generating step of mode 13 or 20. The certification information transmitting section 25, the I/F 78 and step S220 correspond to the certification information transmitting unit of mode 1 or 6. Further, step S220 corresponds to the certification information transmitting step of mode 13 or 20, and the certification information reading section 26, the card reader 86 and step S302 correspond to the certification information acquiring unit of mode 1 or 6. Step S302 corresponds to the certification information acquiring step of mode 13 or 20.

Further, in the above embodiment, the utilization competency judging section 29 and steps S304, S306 correspond to the utilization competency judging unit of mode 1 or 6, and steps S304, S306 correspond to the utilization competency judging step of mode 13 or 20. The print data acquiring section 27, the I/F 78 and steps S308 to S318 correspond to the output data acquiring unit of modes 1 to 3, 6 to 8. Further, steps S308 to S318 correspond to the output data acquiring steps of modes 13 to 15, 20 to 22. The printing section 28, the printer engine 84 and step S320 correspond to the output unit of mode 1 or 6, and step S320 corresponds to the output step of mode 13 or 20.

Further, in the above embodiment, the data server 300 corresponds to the output data storing devices of modes 1 to 3, 5 to 8, 10, 13 to 15, 17, 20 to 22 or 24, and the print data memory section 40 and the memory device 63 correspond to the output data memory unit of mode 1, 2, 20 or 21. Further, the print data receiving section 41, the print data storing section 42, the I/F 98 and steps S402 to S406 correspond to the output data storing unit of mode 1 or 2, and steps S402 to S406 correspond to the output data storing step of mode 20 or 21.

Further, in the above embodiment, the print data transmitting section 43, the I/F 98 and steps S450 to S458 correspond to the output data transmitting unit of mode 1 or 2, and steps S450 to S458 correspond to the output data transmitting step of mode 20 or 21. The print data correspond to the output data of modes 1 to 3, 5 to 8, 10, 12 to 15, 17, 19 to 22 or 24. Further, the printer ID corresponds to the device identification information of mode 2, 7, 14 or 21.

In the above embodiment, the construction is set by arranging the data server 300. However, the invention is not limited to this case, but can also be constructed by arranging the function of the data server 300 in the host terminal 100 instead of the arrangement of the data server 300. In this case, the print data memory section 40, the print data receiving section 41, the print data storing section 42, the print data transmitting section 43 and the status information transmitting section 44 are arranged in the host terminal 100.

In this case, the host terminal 100 corresponds to the device utilizing apparatus of mode 11, and the print data generating section 11 corresponds to the output data generating unit of mode 11. The print data transmitting section 12 corresponds to the generating output data transmitting unit of mode 11, and the print data memory section 40 corresponds to the output data memory unit of mode 11 or 18. Further, the print data storing section 42 corresponds to the output data storing unit of mode 11, and the print data transmitting section 43 corresponds to the output data transmitting unit of mode 11.

Further, the above embodiment is constructed such that the print data are divided and the divided divisional print data are transferred to the plural data servers 300. However, the invention is not limited to this construction, but can also be constructed such that no print data are divided and the same print data are respectively transferred to the plural data servers 300 and the print data are acquired from one of these data servers 300.

Thus, even when the operation of one of the data servers 300 desirous to store the print data is disabled before printing is performed in the network printer 200, the print data can be acquired from one of the other data servers 300. Accordingly, it is possible to further reduce an opportunity in which no printing is performed.

Further, the above embodiment is constructed such that the print data are divided by the number of selection data servers 300, but can also be more particularly constructed such that the print data are divided on the basis of the received status information. For example, the print data are divided in a ratio of the remaining memory capacity of the memory device 63.

Thus, since the print data are divided in consideration of the ability and the resource state of the data server 300, the print data can be further efficiently transferred, stored and acquired.

Further, in the above embodiment, encryption communication is not particularly explained. However, from a view point for improving security, the invention can also be constructed so as to make the communication between the host terminal 100 and the network printer 200, or the communication between the network printer 200 and the data server 300 as encryption communication of SSL (Secure Socket Layer), or the like.

Further, in the above embodiment, the network printer 200 is constructed so as to read the certification information from the authentication card by the card reader 86. However, the invention is not limited to this construction, but can also be constructed so as to input the certification information from the operation panel 80.

Further, the above embodiment is constructed so as to generate the certification information by coding the job ID and the name of the data server 300. However, the invention is not limited to this construction, but can also be constructed so as to generate the certification information by another generating method. As another generating method, for example, a method for generating the certification information in a predetermined rule or at random, and a method for generating the certification information on the basis of information (e.g., temperature, a timer value, a total print number and a total operating time) dynamically changed, in accordance with a state of the network printer 200 are considered.

Further, the above embodiment is constructed by arranging the certification information writing-in section 14 in the host terminal 100. However, the invention is not limited to, this construction, but can also be constructed by arranging the certification information writing-in section 14 separately from the host terminal 100, and communicably connecting the certification information writing-in section 14 and the host terminal 100. In this case, for example, the certification information writing-in section 14 is constructed as a card reader/writer corresponding to a network. This construction is similarly used with respect to the certification information receiving section 13.

Further, in the above embodiment, when each of the processings shown in the flow charts of FIGS. 3, 6, 7, 9, 12 to 14 is executed, the explanation is made with respect to the case in which the control programs stored to the ROMs 52, 72, 92.in advance are executed. However, the invention is not limited to this case, but a program showing these procedures may also be executed from a memory medium storing this program by reading this program into the RAMs 54, 74, 94.

Here, the memory medium includes all memory media if these memory media are a semiconductor memory medium such as RAM, ROM, or the like, a magnetic memory type memory medium such as FD, HD, or the like, an optical reading system memory medium such as CD, CDV, LD, DVD, or the like, and a magnetic memory type/optical reading system memory medium such as MO, or the like and can also be read by a computer irrespective of electronic, magnetic, optical reading methods, or the like.

Further, in the above embodiment, the authentication output system, the network device, the device utilizing apparatus, the output control program, the output request program and the authentication output method in accordance with the invention are applied to the case in which printing is performed in the network printer 200 by utilizing the authentication card as shown in FIG. 1. However, the invention is not limited to this case, but can also be applied to other cases in a scope not departing from the features of the invention. For example, the invention can also be applied to a projector, a home gate way, a personal computer, PDA, a network storage, an audio device, a portable telephone, PHS (registered trademark) (Personal Handyphone System), a watch type PDA, STB (Set Top Box), a POS (Point Of Sale) terminal, a FAX device, a telephone (including an IP telephone, or the like) and other output devices instead of the network printer 200.

What is claimed is:

1. An authentication output system comprising:
a network device for performing an output operation based on output data; and
an output data storing device for storing the output data;
wherein the network device and the output data storing device are communicably connected, and the network device performs the output operation via authentication;
the network device includes:
an output data receiving unit for receiving the output data;
an output data transfer unit for transferring the output data received in the output data receiving unit to the output data storing device;
a certification information generating unit for generating certification information used to certify a utilization competency of the output data;
a certification information transmitting unit for transmitting the certification information generated in the certification information generating unit to a predetermined output destination;
a certification information acquiring unit for acquiring the certification information;
a utilization competency judging unit for judging whether there is the utilization competency of the output data based on the certification information acquired in the certification information acquiring unit;
an output data acquiring unit for acquiring the output data from the output data storing device; and
an output unit for performing the output operation based on the output data acquired in the output data acquiring unit;
the output data acquiring unit acquires the output data from the output data storing device when the utilization competency judging unit judges that there is the utilization competency of the output data; and
the output data storing device includes:
an output data memory unit;
an output data storing unit for storing the output data transferred from the network device to the output data memory unit; and
an output data transmitting unit for transmitting the output data of the output data memory unit to the network device in accordance with an acquiring request from the network device.

2. The authentication output system according to claim 1, wherein the output data transfer unit transfers the output data received by the output data receiving unit and device identification information for discriminating the network device to the output data storing device;
the output data storing unit correspondingly sets and stores the output data transferred from the network device and the device identification information to the output data memory unit;
the output data acquiring unit transmits the acquiring request of the output data including the device identification information to the output data storing device; and
the output data transmitting unit reads the output data corresponding to the device identification information included in the acquiring request from the output data memory unit, and transmits the read output data to the network device specified by this device identification information.

3. The authentication output system according to claim 1, wherein
the network device further includes an output data dividing unit for dividing the output data received in the output data receiving unit,
the output data transfer unit transfers the divisional output data divided in the output data dividing unit to a plurality of the output data storing devices, and
the output data acquiring unit acquires the divisional output data from the plural output data storing devices, and constructs the output data based on the acquired plural divisional output data.

4. The authentication output system according to claim 3, wherein
the output data transfer unit transfers the output data received in the output data receiving unit to each of the plural output data storing devices, and
the output data acquiring unit acquires the output data from one of the plural output data storing devices.

5. The authentication output system according to claims 3, wherein
the network device further includes an output data storing device selecting unit for selecting an output data storing device from the plural output data storing devices based on status information showing at least one of an ability and a resource state of the output data storing device, and
the output data transfer unit transfers the output data to the output data storing device selected by the output data storing device selecting unit.

6. A network device for performing an output operation based on output data, comprising:
an output data receiving unit for receiving the output data;
an output data transfer unit for transferring the output data received in the output data receiving unit to an output data storing device;
a certification information generating unit for generating certification information used to certify a utilization competency of the output data;
a certification information transmitting unit for transmitting the certification information generated in the certification information generating unit to a predetermined output destination;
a certification information acquiring unit for acquiring the certification information;
a utilization competency judging unit for judging whether there is the utilization competency of the output data based on the certification information acquired in the certification information acquiring unit;
an output data acquiring unit for acquiring the output data from the output data storing device; and
an output unit for performing the output operation based on the output data acquired in the output data acquiring unit;
wherein the output data acquiring unit acquires the output data from the output data storing device when the utilization competency judging unit judges that there is the utilization competency of the output data.

7. A device utilizing apparatus for utilizing a network device, comprising:
an output data generating unit for generating the output data;
a generating output data transmitting unit for transmitting the output data generated in the output data generating unit to the network device;
an output data memory unit;
an output data storing unit for storing the output data transferred from the network device to the output data memory unit; and
an output data transmitting unit for transmitting the output data of the output data memory unit to the network device in accordance with an acquiring request from the network device.

8. A device utilizing apparatus for utilizing a network device, and comprising:
an output data generating unit for generating the output data;
a generating output data transmitting unit for transmitting the output data generated in the output data generating unit to the network device;
a certification information receiving unit for receiving certification information transmitted from the network device; and
a certification information output unit for outputting the certification information received in the certification information receiving unit.

9. An output control program for performing an output operation based on output data, and including a program for making a computer execute processing constructed by:
an output data receiving step for receiving the output data;
an output data transfer step for transferring the output data received in the output data receiving step to an output data storing device;
a certification information generating step for generating certification information used to certify a utilization competency of the output data;
a certification information transmitting step for transmitting the certification information generated in the certification information generating step to a predetermined output destination;
a certification information acquiring step for acquiring the certification information;
a utilization competency judging step for judging whether there is the utilization competency of the output data based on the certification information acquired in the certification information acquiring step;
an output data acquiring step for acquiring the output data from the output data storing device; and
an output step for performing the output operation based on the output data acquired in the output data acquiring step;
wherein the output data are acquired from the output data storing device in the output data acquiring step when it is judged in the utilization competency judging step that there is the utilization competency of the output data.

10. An output request program for requesting an output from a network device, comprising a program for making a computer execute processing constructed by:
an output data generating step for generating the output data;
a generating output data transmitting step for transmitting the output data generated in the output data generating step to the network device;
an output data storing step for storing the output data transferred from the network device to output data memory unit; and
an output data transmitting step for transmitting the output data of the output data memory unit to the network device in accordance with an acquiring request from the network device.

11. An output request program for requesting an output from a network device, comprising a program for making a computer execute processing constructed by:
an output data generating step for generating the output data;
a generating output data transmitting step for transmitting the output data generated in the output data generating step to the network device;
a certification information receiving step for receiving certification information transmitted from the network device; and
a certification information output step for outputting the certification information received in the certification information receiving step.

12. An authentication output method in which a network device for performing an output operation based on output data and an output data storing device for storing the output data are communicably connected, and the output operation is performed by the network device via authentication,
wherein, with respect to the network device, the authentication output method includes:
an output data receiving step for receiving the output data;
an output data transfer step for transferring the output data received in the output data receiving step to the output data storing device;
a certification information generating step for generating certification information used to certify a utilization competency of the output data; and
a certification information transmitting step for transmitting the certification information generated in the certification information generating step to a predetermined output destination;
the authentication output method includes an output data storing step for storing the output data transferred from the network device to an output data memory unit with respect to the output data storing device; and
with respect to the network device, the authentication output method further includes:
a certification information acquiring step for acquiring the certification information;
a utilization competency judging step for judging whether there is a utilization competency of the output data based on the certification information acquired in the certification information acquiring step; and
an output data acquiring step for acquiring the output data from the output data storing device when it is judged in the utilization competency judging step that there is the utilization competency of the output data;
the authentication output method further includes an output data transmitting step for transmitting the output data of the output data memory unit to the network device in accordance with an acquiring request from the network device with respect to the output data storing device; and
the authentication output method further includes an output step for performing the output operation based on the output data acquired in the output data acquiring step with respect to the network device.
